(19) United States
(12) Patent Application Publication
(10) Pub. No.: US 2009/0219720 A1
(43) Pub. Date: Sep. 3, 2009

(54) LIGHTING

(76) Inventor: Mark C. Reed, West Chester, OH (US)

Correspondence Address: MCDERMOTT WILL & EMERY LLP, 28 STATE STREET, BOSTON, MA, 02109-1775, US

(21) Appl. No.: 12/040,321

(22) Filed: Feb. 29, 2008

(51) Int. Cl. F21V 7/00; H05K 3/30; B29D 11/00

(52) U.S. Cl. 362/308; 29/832; 264/1.1

(57) ABSTRACT

Lighting assemblies with light sources are disclosed for use in place of fluorescent lights. A support member can be attached to brackets, which can snap into a spring lampholder brackets used for a fluorescent light. For holding a support member, an offset bracket can be used or alternatively, a bracket with a tab or set screw can be used. The disclosed lighting assemblies are particularly well suited for providing light from light emitting diodes. Methods for manufacturing light strip assemblies are also disclosed. Each support member can be positioned on a supporting surface so that a support surface of the light strip is substantially horizontal. A lens can be formed on each light source. Application to refrigerated cases is described.

### FIELD OF THE DISCLOSURE

The present disclosure relates generally to the use of light sources, and more particularly to luminaires and methods of retrofitting applications previously using fluorescent lighting, such as refrigerated display cases. The luminaires and methods of the disclosure are particularly well suited for employing light emitting diodes (LEDs) as light sources.

### BACKGROUND OF THE DISCLOSURE

Display cases are commonly used in retail applications, such as the refrigerated cases in supermarkets and convenience stores, to display merchandise and are commonly arranged into banks of shelving displays or showcase displays for holding goods.

Typically, such display cases are illuminated by fluorescent light fixtures. While providing certain benefits over incandescent lighting, fluorescent lights themselves have inherent power and maintenance requirements and related costs. Fluorescent lights also contain mercury causing substantial environmental concerns and costs.

Certain techniques are currently being used to install alternate sources of lighting in place of fluorescent lights. Such techniques typically require contemporaneous altering of the structural support adjacent to the fluorescent light fixtures, such as by drilling holes. For applications including refrigerated food and beverage displays, such techniques can lead to unnecessary wasted cooling energy, excess labor, and possibly spoiling of the refrigerated items themselves as well as costs related to each.

What is currently lacking, therefore, are lighting systems and installation techniques that provide lighting with reduced power, installation, and maintenance costs compared with fluorescent lighting, particularly for retail goods displays and cases, including refrigerated cases, such as, for example, a retrofit for previous fluorescent lighting assemblies that minimizes replacement and installment costs and downtime of the display or case.

### SUMMARY OF THE DISCLOSURE

The present disclosure is directed to lighting structures, including light strips or luminaires, and methods, in which alternative light sources are utilized in place of fluorescent lights and that can facilitate quick and easy retrofit for previous fluorescent lighting applications. The disclosed techniques and systems (including components and structures) can be particularly useful when employing one or more LEDs as light sources.

An aspect of the present disclosure encompasses light source assemblies utilizing a strip with one or more light sources mounted on a support. The support can comprise more than one support member, such as mating pairs of complementary support members. The support can be attached to one or more brackets that are configured and arranged to fit with or connect to previously installed fluorescent light fixtures or mounting assemblies. For example, the brackets can snap into spring lampholder snap brackets of a previously installed fluorescent light assembly. One or more offset brackets can be used to move the support and light source(s) to a desired location, e.g., out of alignment with a centerline of the pre-existing snap brackets to reduce direct visibility of the support members and/or the light sources. Alternatively, the support can be held by a bracket implemented with a tab and/or set screw used to slip into a hole such as one pre-existing from a fluorescent lampholder.

Another aspect of the present disclosure encompasses related methods for manufacturing LED light strip assemblies or portions thereof. For such manufacturing methods, a light strip of LEDs can be affixed to one or more support members. Each support member can be positioned on a supporting surface so that each LED light strip is substantially in a horizontal position. A lens can be formed (e.g., poured) on each LED, or along an entire circuit board, while the circuit board is in the substantially horizontal position, facilitating a customized lens for a particular application and/or eliminating potential lens damage during storage and prior manufacturing steps. Portions of such manufacturing can take place or be implemented on an assembly line or conveyor belt. The support members can be made of mating pairs of support members. In exemplary embodiments, each member of a pair can include an integrally formed male or female connection.

Other aspects, embodiments, and details of the of present disclosure will be apparent from the following description when read together with the accompanying drawings.

### BRIEF DESCRIPTION OF THE DRAWINGS

Aspects and embodiments of the present disclosure may be more fully understood from the following description when read together with the accompanying drawings, which are to be regarded as illustrative in nature, and not as limiting. The drawings are not necessarily to scale, emphasis instead being placed on the principles of the disclosure. In the drawings:

FIG. 1A depicts a diagrammatic front perspective view of an embodiment of a refrigerated display case with lighting, in accordance with the present disclosure; FIG. 1B depicts a top view of the display case of FIG. 1A;

FIG. 2 depicts a close-up perspective view of a portion of FIG. 1B including a light strip attached by bracket assemblies to a center mullion of the display case;

FIG. 3A depicts a diagrammatic end view of a bracket assembly of FIG. 2; FIG. 3B depicts the view of FIG. 3A with an endplate removed;

FIG. 4 depicts a diagrammatic perspective view of a light strip mounted in a corner of the display case of FIG. 1A and employing a cutoff shield in accordance with an exemplary embodiment of the present disclosure;

FIGS. 5A and 5B depict diagrammatic views of a light strip mounted with brackets including a tab and set screw for a retrofit application, in accordance with an alternate embodiment of the present disclosure; FIGS. 5C-5F depict close-up perspective views of brackets shown and described for FIGS. 5A and 5B; FIG. 5G is a photograph of a pre-existing fluorescent lampholder, for which embodiments shown in FIGS. 5A-5F may be used as retrofit installations.

FIGS. 6A-6B depict perspective and side views of an assembly line process of manufacturing a light strip assembly, in accordance with a further embodiment of the present disclosure;

FIG. 7 depicts a flow chart for a method, in accordance with an exemplary embodiment of the present disclosure; and

FIG. 8 depicts a cross section view of an alternate light source lens used with luminaires of the present disclosure.

While certain embodiments are depicted in the drawings, one skilled in the art will appreciate that the embodiments depicted are illustrative and that variations of those shown, as well as other embodiments described herein, may be envisioned and practiced within the scope of the present disclosure.

### DETAILED DESCRIPTION

Aspects and embodiments of the present disclosure provide luminaires and methods, in which alternative light sources (LEDs in exemplary embodiments) are utilized in place of, or replacing, fluorescent lights. While the preferred embodiment employs LED light sources, other light sources may also be employed or alternatively used within the scope of the present disclosure. By way of example only, other light sources such as plasma light sources may be used. Further, the term “LEDs” is intended to refer to all types of light emitting diodes including organic light emitting diodes or “OLEDs”. Such lighting according to the present disclosure can be used to retro-fit existing lighting assemblies and applications that utilize fluorescent lighting. Use of such lighting techniques can afford reduced energy and maintenance as well as reduced installation time and costs when compared to existing techniques.

While generally applicable to the retrofitting of most fluorescent light applications, embodiments of the present disclosure may be particularly well-suited for application of retro-fitting of refrigerated food cases such as those commonly found in supermarkets and convenience stores. Such refrigerated cases, can include cases for chilled foods and/or drinks, as well as those used to display frozen foods.

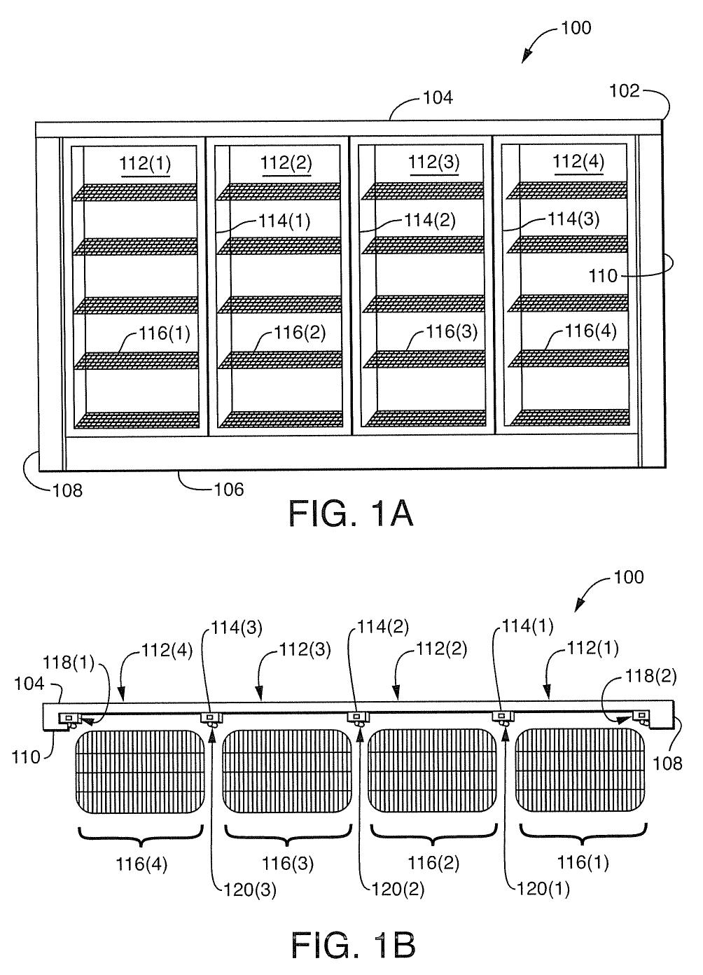

FIG. 1A depicts a diagrammatic front perspective view of an embodiment 100 of lighting for a refrigerated display case, in accordance with the present disclosure that employs LEDs to emit light.

As can be seen in FIG. 1A, a refrigerated case 102 can include top and bottom frame members 104, 106 that are separated by side members 108, 110. The case 102 can include multiple doors, such as doors 112(1)-112(4) having transparent or translucent portions, such as by utilization of glass, clear plastic, or the like. Doors 112(1)-112(4) can be separated by mullions 114(1)-114(3) positioned between top and bottom members 104, 106. A number of shelves can be located within the case 102, such as the shelf stacks 116(1)-116(4) located behind the door 112(1)-112(4), as shown.

FIG. 1B depicts a top view of the embodiment 100 of FIG. 1A. Corner light strips 118(1), 118(2) are located in the interior of case 102 adjacent the junctions of side members 108 and 110, respectively, with top member 104. Center light strips 120(1)-120(3) are located on the interior of case 102, adjacent to mullions 114(1)-114(3). The horizontal area of stacked shelving, e.g., 116(1)-116(4), can be seen in FIG. 1B.

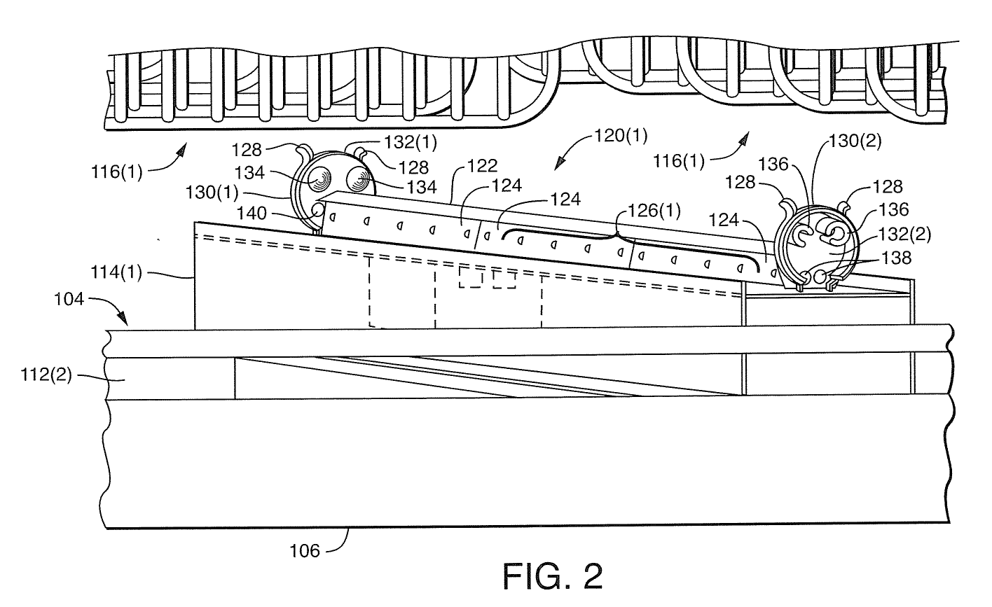

FIG. 2 depicts a close-up perspective view of a portion of FIG. 1B including a light strip 120(1) attached by bracket assemblies, including cylindrical brackets 130(1), 130(2) and offset members 132(1), 132(2), to center mullion 114(1) on the interior of case 102, i.e., the refrigerated area of the case removed from the walking area afforded to the general public. Center mullion 114(1) connects top and bottom case members 104, 106 adjacent door 112(2), as shown. Shelf stacks 116(1) and 116(2) are also shown.

Light strip 120(1) includes a support member 122 having opposed ends that are held relative to snap brackets 128 by the bracket assemblies 130(1), 130(2), 132(1) and 132(2). In embodiments utilizing circuitry driven light sources such as LEDs, the support member 122 can have one or more printed circuit boards 124 of any size mounted on its surface. An inline configuration of three printed circuit boards 124 is shown in FIG. 2. The same or different configuration of one or more printed circuit boards (“PCB”) 124 could be present on the other side of support member 122 (and such would be hidden due to the perspective of the drawing). Each PCB 124 can include a plurality of light sources 126(1).

The bracket assemblies can include a pair of cylindrical brackets 130(1), 130(2) and a pair of offset members or brackets 132(1), 132(2). Each cylindrical bracket can be configured to fit within a snap bracket 128, which can be of the configuration commonly used for holding a fluorescent light bulb. Suitable fasteners (e.g., screws, bolts, press-fit dowels, etc.) 134 and 138 may be used for the connections between the support member and/or the cylindrical brackets 130(1), 130(2).

FIG. 2 depicts the cylindrical brackets 130 and offset members 132 holding an end of the support member 122 in a snap bracket 128, such as that from a pre-existing fluorescent light fixture. Quick retrofit of a fluorescent light fixture with a light strip or luminaire according to the present disclosure is thus facilitated by simply removing the pre-existing fluorescent light bulb from the snap brackets 128 and inserting the light strip or luminaire. One or more portions of pre-existing wiring from a fluorescent system may be used with embodiments of the present disclosure. When retrofitting a fluorescent system with an LED based system, it may be desirable or necessary, depending on the circuitry and system requirements to replace the power supply or to otherwise regulate the power, as required or desirable for the chosen light sources, as will be recognized by those skilled in the art.

In exemplary embodiments, PCB 124 can include FR4 as printed circuit board material. Other epoxy-glass laminates may also be used. Solder pads can be present on each end of each PCB 124 for wire attachment.

In an exemplary embodiment in which LEDs are employed as the light sources, an assembly of LEDs (e.g., preferably a strip of LEDs) can be utilized with one or more light boards having power and control circuitry for the LEDs; such boards can provide one or more substrates on or in which each LED and other components of the assembly can be created or deposited, such as LEDs themselves, and a related optical element (such as a lens or other refractive element, or a reflector) for directing at least a portion of the light emitted from the LED. An LED assembly can hold one or more LEDs, and one or more optics (or optical elements), to a board, and can define the positioning of the one or more optics with respect to the LEDs. The optics can be positioned over each of the LEDs, respectively; a single optical element, e.g., a single cylindrical lens or a poured plastic lens, etc., can be positioned for use with one or more LEDs. Suitable examples of LED and optic trays that hold the optics in position with respect to LEDs on a printed circuit board are described in U.S. Patent Publication No. 2006/146531 and in U.S. Provisional Patent Application No. 60/981,984; the entire contents of both of which applications are incorporated herein by reference.

The LEDs of this exemplary embodiment can be of any kind, color (e.g., emitting any color or white light or mixture of colors and white light as the intended lighting arrangement requires) and luminance capacity or intensity, preferably in the visible spectrum. Color selection can be made as the intended lighting arrangement requires. In accordance with the present disclosure, LEDs can comprise any semiconductor configuration and material or combination (alloy) that produce the intended array of color or colors. The LEDs can have a refractive optic built-in with the LED or placed over the LED, or no refractive optic; and can alternatively, or also, have a surrounding reflector, e.g., that re-directs low-angle and mid-angle LED light outwardly. In one suitable embodiment, the LEDs are white LEDs each comprising a gallium nitride (GaN)-based light emitting semiconductor device coupled to a coating containing one or more phosphors. The GaN-based semiconductor device can emit light in the blue and/or ultraviolet range, and excites the phosphor coating to produce longer wavelength light. The combined light output can approximate a white light output. For example, a GaN-based semiconductor device generating blue light can be combined with a yellow phosphor to produce white light. Alternatively, a GaN-based semiconductor device generating ultraviolet light can be combined with red, green, and blue phosphors in a ratio and arrangement that produces white light (or another desired color). In yet another suitable embodiment, colored LEDs are used, such are phosphide-based semiconductor devices emitting red or green light, in which case the LED assembly produces light of the corresponding color. In still yet another suitable embodiment, the LED light board includes red, green, and blue LEDs distributed on the printed circuit board in a selected pattern to produce light of a selected color using a red-green-blue (RGB) color composition arrangement. In this latter exemplary embodiment, the LED light board can be configured to emit a selectable color by selective operation of the red, green, and blue LEDs at selected optical intensities. Clusters of different kinds and colors of LED is also contemplated to obtain the benefits of blending their output.

Each PCB 124 can include an onboard driver to run the light sources, e.g., LEDs, with a desired current. For example, a current suitable for an LED may be used. For example, a representative current range could include, but is not limited to about 250 mA to about 800 mA; one exemplary current is about 350 mA. A circuit board 124 can have a bus, e.g., a 24V DC bus, going from one end to the other. Other voltages may of course be used for a bus. Any suitable number of suitable LEDs 126 can be disposed on a light strip board. In one illustrative example, five (5) Rebel LEDs (LUXEON® Rebel LEDs as made commercially available by the Philips Lumileds Lighting Company)—operational at 80 Lumens minimum may be employed with the luminaire of the present disclosure. Other suitable LEDs or alternative light sources and output values may be used within the scope of the present disclosure.

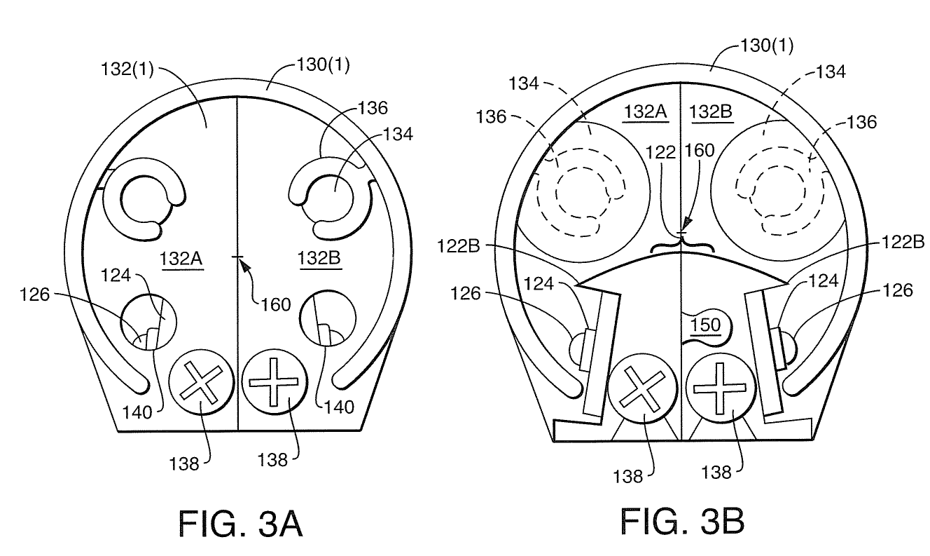

Referring now to FIG. 3A, a diagrammatic end view of a bracket assembly of FIG. 2 is shown including cylindrical bracket 130(1) configured with offset member 132(1). The cylindrical bracket 130(1) may include one or more bosses or reinforced ribs 136 which may provide for a connection with the offset member 132(1). The bracket may be secured mechanically by any suitable mechanical connection 134, e.g., Velcro®, a screw, a pressed fit dowel, or rivet, etc. The cylindrical bracket 130(1) can optionally include one or more apertures or holes 140 through which wiring can be run. Fasteners (e.g., bolts or screws) 138 can be present for attachment of offset member 132(1) to an adjacent support member 122. As described previously for FIG. 2, cylindrical bracket 130(1) can be configured to fit within a standard snap bracket 128 used to hold fluorescent bulbs. Center line 160 indicates the centerline of such a corresponding snap bracket 128.

FIG. 3B depicts the view of FIG. 3A with an offset member 132(1) removed to show the relation between the cylindrical bracket 130(1), support member 122, and circuit boards 124. The cylindrical bracket 130(1) is shown relative to the support member 122, the circuit boards 124 and the LEDs 126, as would be the configuration for a retrofit application to a pre-existing fluorescent lighting assembly including snap brackets 128 of FIG. 2. The outlines of the heads of fasteners 134 are shown in relation to bosses 136. Representative A centerline 160, representative of pre-existing lamp holder (or snap) brackets is shown as well.

As shown in FIG. 3B, exemplary embodiments of support member 122 can include two support members 122A-122B of complementary configuration that fit together. For example, the depicted embodiment comprises an exemplary male-female mating configuration 150 facilitating connection. As shown, the male-female elements of the support members 122A, 122B may, but need not be, integrally formed into the support members themselves.

In exemplary embodiments (e.g., as shown for FIGS. 3A-3B), offset members 132(1), 132(2) can be configured to allow support member 122 and attached light source(s) 126 to be positioned off of the centerline (160 of FIG. 3A) of a receiving snap bracket 128. Such configurations can allow the LEDs to positioned at a desired location, e.g., closer to a center mullion or adjacent structural support member of a cooler. Observation of the support members 122A, 122B and the light sources 126 by individuals outside of a display case can accordingly be reduced or altogether eliminated, representing an advantage over prior art fluorescent lighting. If removing the luminaire from sight is not necessary or is otherwise facilitated by the location of the luminaire with respect to the structure on which it is mounted, then the offset members 132(1), 132(2) may locate the support members 122A, 122B on the centerline 160 or anywhere in relation thereto. The word “offset” in the term “offset member” merely refers to the depicted exemplary embodiment and is not intended to be limiting as to whether the support must be offset from the centerline 160. For example, portions of the support members 122A, 122B can overlap a centerline 160 for some embodiments.

In exemplary embodiments, support members 122A, 122B may be made by extrusion of 6063T5 aluminum alloy constructed according to known extrusion techniques. In exemplary embodiments, cylindrical bracket 130(1) can be made of 6063T5 aluminum alloy. Moreover, in an exemplary embodiment, the offset members 132 can be formed of suitable metal such as a sheet of aluminum alloy (e.g., with a thickness of 0.050 inches). Other suitable materials, e.g., plastics, may be used in addition to or substitution for the ones previously described for the support members, brackets and/or members.

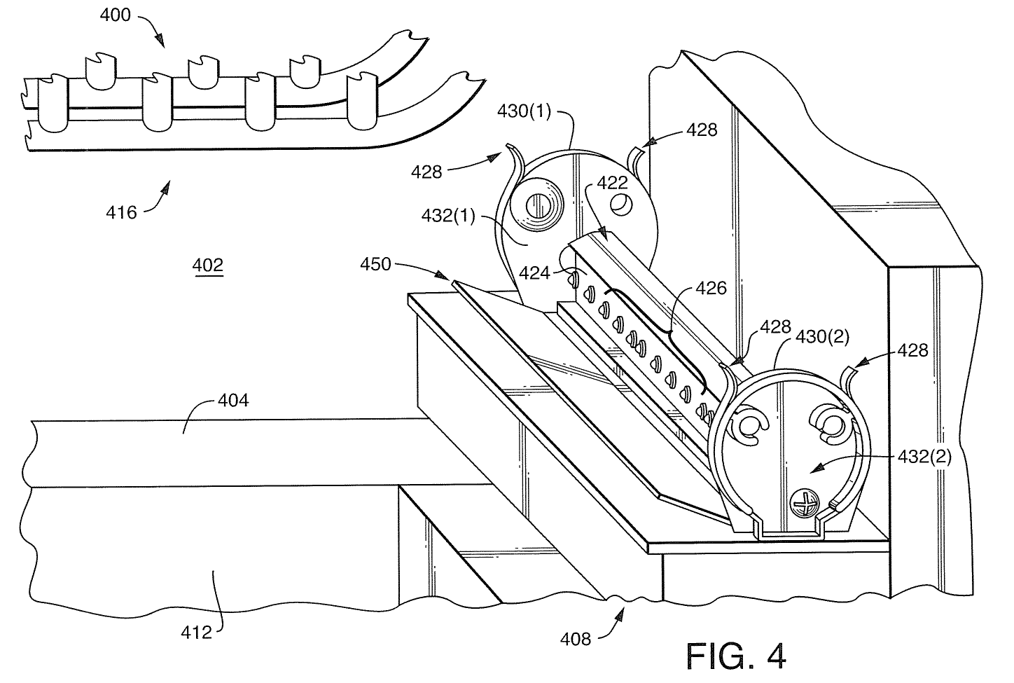

Referring now to FIG. 4, a diagrammatic perspective view is depicted of an exemplary embodiment of a light strip 400, in accordance with the present disclosure. Light strip 400 is positioned in a corner configuration inside of a refrigerated case 402 with shelving 416. Light strip 400 can include a support member 422 holding a circuit board 424 that includes a number of light sources 426 necessary for casting the desired amount of light onto the display area of the case 402.

Similar to the embodiment shown in FIGS. 1-3, cylindrical brackets 430(1)-430(2) and offset members 432(1)-(2) may be used to hold support member 422 fixed relative to snap brackets 428, such as, for example, may have been used with a pre-existing fluorescent lighting fixture.

Also shown in FIG. 4 is an optional visual cutoff shield 450 that can be present for control of the light output of the light sources or prevention of direct observation of the light sources or support members 422A, 422B by customers outside case 402. The optional visual cutoff shield 450 can be, but need not be, reflective to assist in directing light emitted from the light sources. Any suitable material can be used for cutoff shield 450. For example, in an exemplary embodiment, aluminum sheet metal of thickness of 30 or 40 mils (0.030 inch or 0.040 inch), painted all black, with a gloss finish can be used for shield 450. Other materials and finishes may of course be used within the scope of the present disclosure. Additionally, reflective material may be placed on or adjacent to the adjacent mullion 114 to reflect light into the case. Alternatively, in a retrofit application, reflective material may already exist on the mullion for redirecting light from a pre-existing fluorescent bulb.

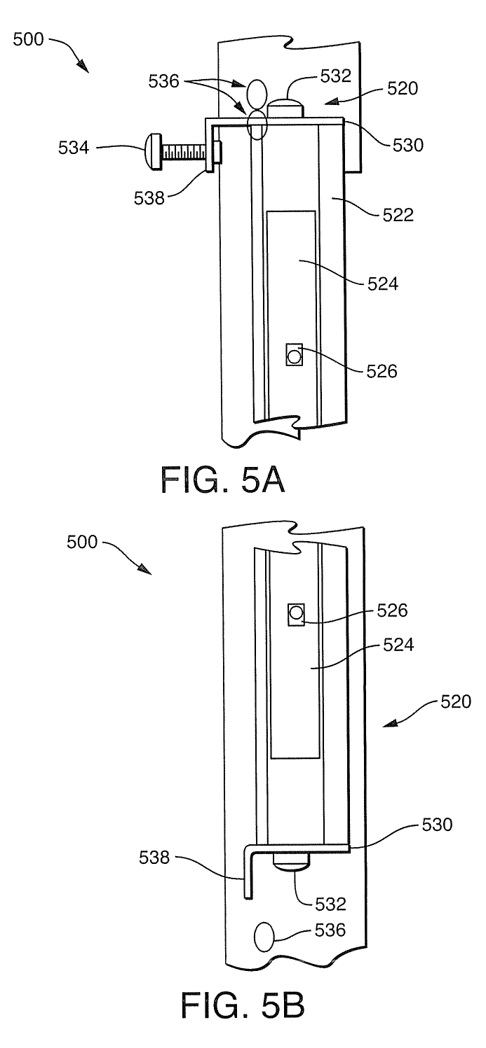

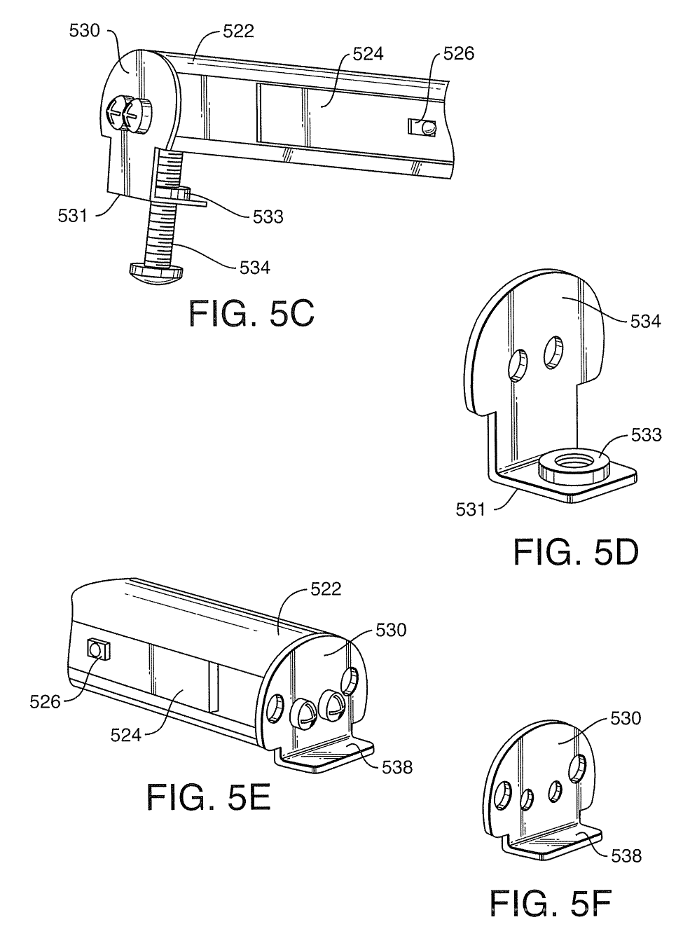

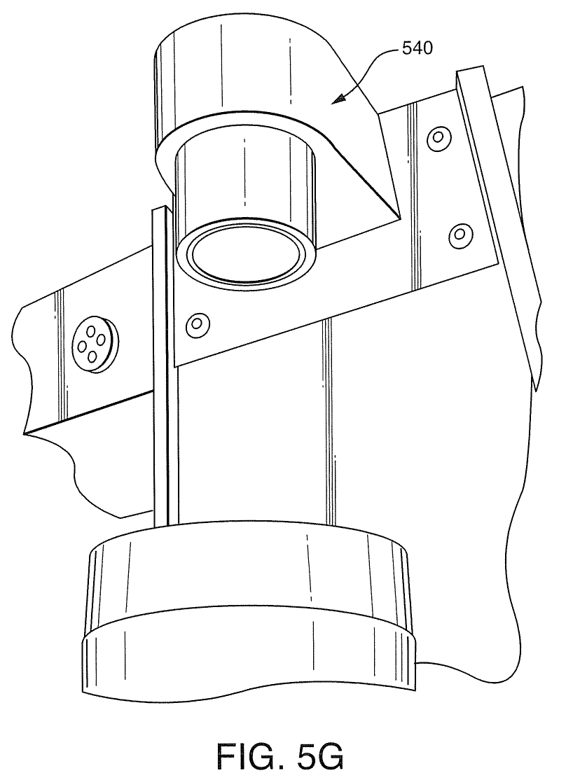

FIGS. 5A-5B depict diagrammatic views of an alternative embodiment 500 in accordance the present disclosure, including a light strip used in conjunction with brackets and a set screw. Referring to FIG. 5A, support member 522 can be used to support printed circuit board 524 having LEDs or other light sources 526. Board 524 can be supported in a desired orientation relative to mullion 520. Instead of a cylindrical bracket coupled to a plate bracket, as with the embodiments depicted in FIGS. 1-4, embodiment 500 includes a plate bracket 530 used in conjunction with a set screw 534 to hold the light strip support member 522 to the mullion 520.

Bracket 530 may include a tab 538 configured to pass through a hole 536 in the mullion 520 as shown. A fastener (e.g., bolt) 532 may be used to connect bracket 530 to light strip support member 522. Set screw 534 may be used to secure the connection between mullion 520 and support member 522. Hole(s) 536 may be pre-existing holes, already having been formed for a pre-existing fluorescent lighting fixture.

FIG. 5B depicts the other end of the support member 522 shown in FIG. 5A as positioned relative to mullion 520. Bracket 530 may include tab 538 and may be used with fastener 532 to secure light strip support member 522 to mullion 520. A dowel or pin may optionally be included with tab 538 to extend through a hole 536 in the mullion 520. A set-screw is not required.

FIGS. 5C-5F depict close-up perspective views of brackets shown and described for FIGS. 5A-5B. In FIG. 5C, bracket 530 is shown in conjunction with set screw 534. Bracket 530 is secured to support member 522, which supports printed circuit board 524 with LED 526. Bracket 530 includes a tab portion 531 that can be configured with a threaded portion 533 to receive set screw 534. FIG. 5D depicts a perspective view of the bracket 530 shown in FIG. 5C.

In FIG. 5E, bracket 530 is shown secured to support member 522, which supports PCB 524 with LED 526. Bracket 530 includes a tab portion 538 that can be configured to interface or connect with a previously installed hole for a fluorescent lampholder, e.g., as shown in FIG. 5G. A perspective view of the bracket 530 of FIG. 5E is shown in FIG. 5F.

FIG. 5G is a photograph of a prior art pre-existing fluorescent lamp holder 540, for which embodiments shown in FIGS. 5A-5F could be used as retrofit installations. The lampholder 540 would removed (both top and bottom) allowing for the installation of set-screw design, e.g., as shown in FIGS. 5A-5F.

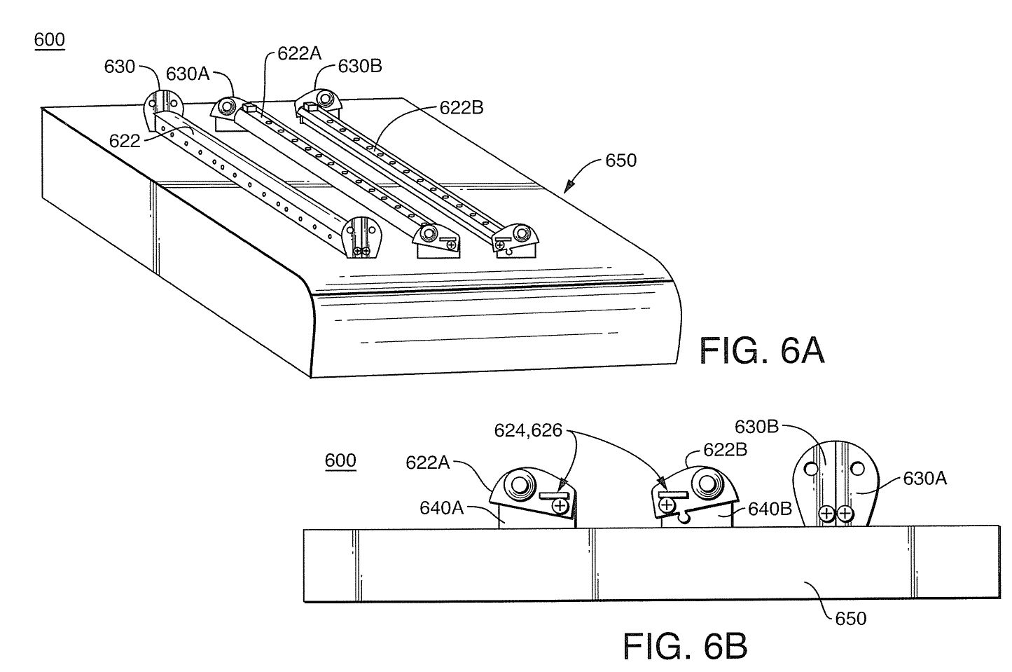

FIGS. 6A-6B depict perspective and side diagrammatic views, respectively, of an assembly line manufacturing process 600 for providing light sources such as LEDs mounted on a support member 622 with lenses, in accordance with a further embodiment of the present disclosure. As shown, one or more support members 622A-622B may be placed on a support surface 650 in such a way that a circuit board 624 with light sources 626, such as LEDs, is held in a horizontal or substantially horizontal position. Support members 622A-622B may have end plates 630A-630B, respectively. Support surface 650 may be part of an assembly line or conveyor belt, in exemplary embodiments.

When circuit board 624 is in a substantially horizontal position, a lens can be formed on each light source 626 (or one or more light sources). For example, a plastic lens may be formed by pouring a plastic-containing liquid with suitably colored or transparent plastic over each light source 626, and then allowing the plastic to cool or cure (or otherwise causing the plastic to harden). In such a way, a lens of desired shape can be formed over each light source. In certain embodiments, lens materials including the following may be used: Lord Corporation Urethane model 7550, or Momentive (formerly GE) silicone models: TSE397, TSE397 or RTV 615.

Where the configuration of the support members does not alone facilitate orienting the circuit board horizontally, the support members may be placed on one or more related bases or supports to facilitate horizontal orientation. In the depicted embodiment of FIGS. 6A-6B, the specific shape of support members 622A, 622B may not necessarily provide a horizontal or substantially horizontal orientation of the related circuit board when the support members are placed on a horizontal surface. Accordingly, each support member 622A, 622B can be placed on a base (e.g., trays 640A, 640B in FIG. 6B) having a corresponding configuration to accept the support members 622A, 622B in a manner orienting the circuit board(s) horizontally for lens application. In an embodiment, such a base, e.g., base 640A, can be constructed from suitable material including, but not limited to, milled-plastic, wood, or the like. Other bases/platforms and manners of constructing the same will be apparent to those skilled in the art.

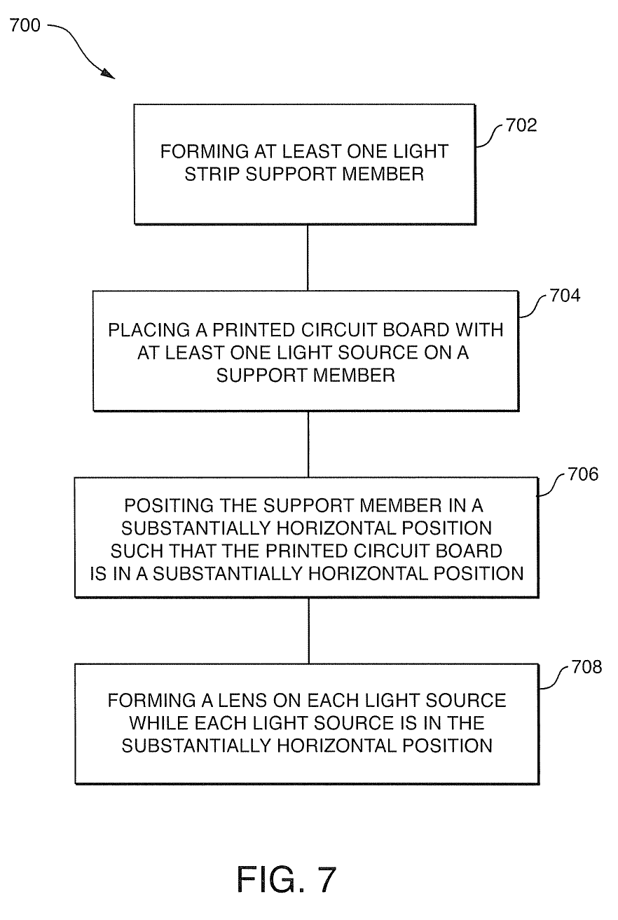

Referring to FIG. 7, a flow chart is depicted for a fabrication/construction method 700, in accordance with an exemplary embodiment of the present disclosure. For method 700, at least one support member for a lighting assembly can be formed, as described at 702. In exemplary embodiments, two support members may be formed of extruded aluminum and these members may optionally include an integrally formed male-female connection, although other suitable connection are contemplated within the scope of the present disclosure. A printed circuit board with a plurality of light sources can be affixed to each support member, as described at 704. Each support member can be positioned in a substantially horizontal position, as described at 706. In exemplary embodiments, the support member(s) can be placed in a horizontal position on an assembly line or conveyor belt. A lens can then be formed on each light source while each light source and the circuit board is in the substantially horizontal position, as described at 708. In exemplary embodiments, a plastic containing liquid with plastic of a desired transparency and/or color may be poured onto each light source to cure and form the lens according to standard techniques known to those of ordinary skill in the art.

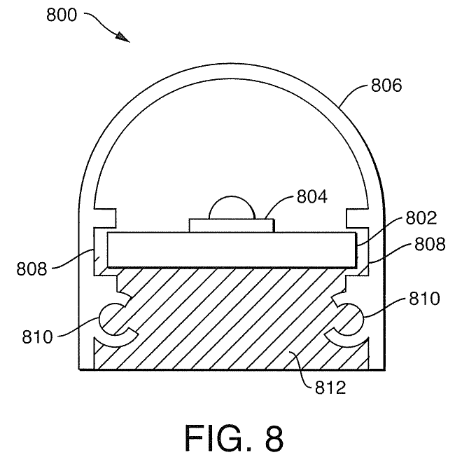

FIG. 8 depicts a cross section view of an alternate lens embodiment 800 used for a light strip or luminaire according to the present disclosure. A printed circuit board 802 can support one or more LEDs 804, similar to previously described embodiments. Instead of a lens formed over an individual LED or LED assembly, a plastic lens 806, e.g., one that is semicylindrical in shape, may be configured around the circuit board 802 and LEDs 804 as shown. The assembly of the board 802, LEDs 804, and lens 806 can be mounted to brackets, for example by way of screws (not shown) and screw pockets 810, and used for retrofit into prior fluorescent lighting applications, similar to previously described embodiments of the present disclosure.

Continuing with the description of FIG. 8, board 802 can be received by one or more grooves 808 in lens 806. In exemplary embodiments, heat removal material 812 may be located adjacent board 802 as shown for heat removal, i.e., dissipation of heat generated by LEDs 804. Material 812 can be selected as desired, and material selection can be based on heat removal/thermal conductance characteristics. In exemplary embodiments, potting compound can be utilized for material 812.

In exemplary embodiments, lens 806 is made of an extrusion of polycarbonate. Such polycarbonate or other plastic may be selected as desired and may possess a desired degree of transparency (and, therefore, opaqueness) and may have a desired color.

In further embodiments, the formation of at least one support member can include forming a circuit board supporting face in the support member that is configured and arranged to support the circuit board (and attached light sources) in a desired orientation, e.g., as when the related assembly is placed in a retrofit application. A visual cutoff shield may also be mounted to a support member for some applications.

Accordingly, embodiments of lighting techniques according to the present disclosure can be used to retro-fit existing lighting assemblies and applications that were initially constructed to utilize fluorescent lighting. Such lighting according to the present disclosure can afford reduced energy, maintenance, and installation costs, as well as reduced installation time when compared to existing techniques. As described previously, exemplary embodiments of the present disclosure can utilize LEDs as light sources.

While certain embodiments have been described herein, it will be understood by one skilled in the art that the methods, systems, and apparatus of the present disclosure may be embodied in other specific forms without departing from the spirit thereof. For example, while aspects and embodiments herein have been described in the context of retrofit applications for refrigerated display cases, the present disclosure is not limited to such; for example, embodiments of the present disclosure may be utilized generally for any retro-fit applications to pre-existing fluorescent lighting structures and fixtures.

Accordingly, the embodiments described herein, and as claimed in the attached claims, are to be considered in all respects as illustrative of the present disclosure and not restrictive.

What is claimed is:

1. A lighting assembly, comprising:
at least one support member having opposing ends and a surface for supporting a circuit board;
at least one circuit board having at least one light source, wherein the at least one circuit board is affixed to the surface of the at least one support member; and
a plurality of brackets configured and arranged to hold the support member by the opposing ends, wherein the bracket is configured and arranged for attachment to a fluorescent light attachment.

2. The lighting assembly of claim 1, wherein the plurality of brackets comprise a pair of cylindrical brackets each configured and arranged to be received by a snap-in bracket of a fluorescent lamp holder, and a pair of offset brackets each configured and arranged to be attached to a respective one of the cylindrical brackets and to hold an opposing end of the support member.

3. The lighting assembly of claim 1, wherein the plurality of brackets comprise a pair of brackets each configured and arranged to hold an opposing end of the support member and to connect with a pre-formed hole for a fluorescent light fixture.

4. The lighting assembly of claim 3, wherein one bracket further comprises a threaded connection for a set screw.

5. The lighting assembly of claim 3, wherein one bracket further comprises a tab.

6. The lighting assembly of claim 5, wherein the tab comprises a dowel configured and arranged to fit into a pre-formed hole for a fluorescent light fixture.

7. The lighting assembly of claim 1, wherein the pair of brackets includes one or more fasteners configured and arranged to fasten the support member to a respective bracket.

8. The lighting assembly of claim 7, wherein the one or more fasteners comprise a bolt, dowel, or screw.

9. The lighting assembling of claim 7, wherein the pair of brackets comprise a threaded connection for receiving a bolt.

10. The lighting assembly of claim 1, wherein the at least one support member comprises two support members.

11. The lighting assembly of claim 10, wherein the two support members comprise a mating connection comprising male and female portions.

12. The lighting assembly of claim 11, wherein the male and female portions are each disposed on a respective support member.

13. The lighting assembly of claim 1, wherein the at least one support member comprises extruded aluminum.

14. The lighting assembly of claim 1, wherein the at least one support member comprises plastic.

15. The lighting assembly of claim 1, wherein the at least one circuit board comprises FR4 or an epoxy-glass laminate.

16. The lighting assembly of claim 1, wherein the at least one light source comprises one or more LEDs.

17. The lighting assembly of claim 16, wherein the at least one circuit board comprises an onboard driver to run one or more LEDs.

18. The lighting assembly of claim 17, wherein the onboard driver is configured and arranged to operate the one or more LEDs by supplying power at a desired current level.

19. The lighting assembly of claim 18, wherein the current level is in a range of about 250 mA to about 800 mA.

20. The lighting assembly of claim 19, wherein the current level is about 350 mA.

21. The lighting assembly of claim 1, wherein the at least one circuit board comprises a DC bus going from one end to the other.

22. The lighting assembly of claim 21, wherein the DC bus is a 24V DC bus.

23. The lighting assembly of claim 16, wherein the one or more LEDs comprise one or more white-light emitting LEDs.

24. The lighting assembly of claim 1, further comprising a cutoff shield configured and arranged to direct light emitted from the light sources.

25. The lighting assembly of claim 16, further comprising at least one lens configured and arranged to receive light emitted from the one or more LEDs.

26. The lighting assembly of claim 25, wherein the at least one lens comprises a lens in contact with respective assemblies of the one or more LEDs.

27. The lighting assembly of claim 25, wherein the at least one lens comprises a cylindrical lens spaced apart from the respective assemblies of the one or more LEDs.

28. A method of manufacturing a light strip assembly, the method comprising:
forming at least one support member;
placing a printed circuit board with at least one light source on the at least one support member;
positioning the at least one support member on a support surface, wherein the printed circuit board is in a substantially horizontal position; and
forming a lens on each light source while the light source is in the substantially horizontal position.

29. The method of 28, wherein forming a lens on each light source comprises pouring a liquid containing plastic on each light source.

30. The method of claim 28, wherein forming at least one support member comprises attaching first and second support members to one another.

31. The method of claim 30, wherein attaching the first and second support members to one another comprises using a male and female joint.

32. The method of claim 31, wherein using a male and female joint comprises using corresponding male and female joints integrally formed in the first and second support members respectively.

33. The method of claim 28, wherein forming the at least one support member includes forming a metal extrusion.

34. The method of claim 33, wherein the metal extrusion is aluminum.

35. The method of claim 28, wherein forming the at least one support member includes forming a supporting face in the at least one support member that is configured and arranged to support a printed circuit board in a desired orientation.

36. The method of claim 28, further comprising attaching at least one bracket to the at least one support member, wherein the bracket is configured and arranged to hold the support member to a pre-existing fluorescent lighting structure.

37. The method of claim 36, wherein the pre-existing fluorescent lighting structure comprises snap tabs, and further comprising moving the at least one support member away from a centerline of snap tabs of the pre-existing fluorescent lighting structure.

38. The method of claim 37, wherein moving the at least one support member away from the centerline of the snap tabs comprises moving the at least one support member towards a structural support attached to the snap tabs.

39. The method of claim 28, wherein the at least one light source comprises at least one LED.
